(19) United States
(12) Patent Application Publication
(10) Pub. No.: US 2024/0056058 A1
(43) Pub. Date: Feb. 15, 2024

(54) FIR FILTER, FILTERING METHOD BY FIR FILTER, AND NON-TRANSITORY COMPUTER READABLE MEDIUM STORING CONTROL PROGRAM

(71) Applicant: NEC Corporation, Tokyo (JP)

(72) Inventor: Eita Kobayashi, Tokyo (JP)

(73) Assignee: NEC Corporation, Tokyo (JP)

(21) Appl. No.: 18/223,349

(22) Filed: Jul. 18, 2023

(30) Foreign Application Priority Data
Aug. 10, 2022 (JP) 2022-128165

(51) Int. Cl. H03H 17/02

(52) U.S. Cl. CPC H03H 17/0227; H03H 17/0226; H03H 2218/085

(57) ABSTRACT

An FIR filter includes: an address signal generation unit configured to generate an address signal of an address value in accordance with k bit values that correspond to k filter coefficients having a symmetric property; and an extraction unit configured to extract a computation result that corresponds to the address value indicated by the address signal from the table, in which, in the table, a plurality of computation results in which sets of computation results indicating the same values among 2 to the power of k patterns of computation results which are obtained by adding up k results of multiplication, the k results of multiplication being results obtained by multiplying each of k filter coefficients having a symmetric property by each of k bit values that correspond to k filter coefficients are commonly shared, and the plurality of address values are associated with each other.

### INCORPORATION BY REFERENCE

This application is based upon and claims the benefit of priority from Japanese patent application No. 2022-128165, filed on Aug. 10, 2022, the disclosure of which is incorporated herein in its entirety by reference.

### TECHNICAL FIELD

The present disclosure relates to an FIR filter, a filtering method by an FIR filter, and a non-transitory computer readable medium storing a control program.

### BACKGROUND ART

In recent years, in an FIR filter, which is one type of a digital filter, the number of taps provided has been increasing in order to satisfy the demand for improved processing performance, and the size of the circuit has had to be dramatically increased in accordance with the increase in the number of taps.

One solution to the above problem is disclosed, for example, in Japanese Unexamined Patent Application Publication No. 2003-298398. A digital filter computation processing circuit disclosed in Japanese Unexamined Patent Application Publication No. 2003-298398 makes filter coefficients have a symmetric property. Accordingly, the number of times of multiplication in a case in which filter coefficients have a symmetric property is half of that in the case in which filter coefficients do not have a symmetric property. Accordingly, in this processing circuit, the number of multiplication circuits can be reduced, whereby it is possible to prevent the size of the circuit from being increased.

However, there is a problem in the processing circuit disclosed in Japanese Unexamined Patent Application Publication No. 2003-298398 that, since the size of each multiplication circuit is large, the size of the entire circuit is still large.

### SUMMARY

One of objects of the present disclosure is to provide an FIR filter, a filtering method by an FIR filter, and a control program that solve the aforementioned problem.

An FIR filter according to one aspect of the present disclosure includes: an address signal generation unit configured to generate an address signal of an address value in accordance with k (k is an integer equal to or larger than two) bit values that correspond to k filter coefficients having a symmetric property; a storage unit configured to store a table in which a plurality of address values and a plurality of computation results are associated with each other; and an extraction unit configured to extract a computation result that corresponds to the address value indicated by the address signal generated by the address signal generation unit from the table, in which, in the table, a plurality of computation results in which sets of computation results indicating the same values among 2 to the power of k patterns of computation results which are obtained by adding up k results of multiplication, the k results of multiplication being results obtained by multiplying each of k filter coefficients having a symmetric property by each of k bit values that correspond to k filter coefficients are commonly shared, and the plurality of address values are associated with each other.

A filtering method by an FIR filter according to one aspect of the present disclosure is a filtering method by an FIR filter, the filtering method including: generating an address signal of an address value in accordance with k (k is an integer equal to or larger than two) bit values that correspond to k filter coefficients having a symmetric property; extracting a computation result that corresponds to the address value indicated by the generated address signal from a table in which a plurality of address values and a plurality of computation results are associated with each other, the table being stored in a storage apparatus, in which in the table, a plurality of computation results in which sets of computation results indicating the same values among 2 to the power of k patterns of computation results which are obtained by adding up k results of multiplication, the k results of multiplication being results obtained by multiplying each of k filter coefficients having a symmetric property by each of k bit values that correspond to k filter coefficients are commonly shared, and the plurality of address values are associated with each other.

A control program according to one aspect of the present disclosure is a control program for causing a computer to execute: processing for generating an address signal of an address value in accordance with k (k is an integer equal to or larger than two) bit values that correspond to k filter coefficients having a symmetric property; and processing for extracting a computation result that corresponds to the address value indicated by the generated address signal from a table in which a plurality of address values and a plurality of computation results are associated with each other, the table being stored in a storage apparatus; in which, in the table, a plurality of computation results in which sets of computation results indicating the same values among 2 to the power of k patterns of computation results which are obtained by adding up k results of multiplication, the k results of multiplication being results obtained by multiplying each of k filter coefficients having a symmetric property by each of k bit values that correspond to k filter coefficients are commonly shared, and the plurality of address values are associated with each other.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a diagram showing a configuration example of an FIR filter according to a first example embodiment;

FIG. 2 is a diagram showing a specific configuration example of the FIR filter according to the first example embodiment;

FIG. 3 is a diagram for describing a method for determining setting contents in a table used in the FIR filter according to the first example embodiment;

FIG. 4 is a diagram showing one example of the setting contents in the table used in the FIR filter according to the first example embodiment;

FIG. 5 is a diagram showing correspondence between input values, address values, and computation results in the FIR filter according to the first example embodiment;

FIG. 6 is a diagram for describing a method for determining the setting contents in the table used in a first modified example of the FIR filter according to the first example embodiment;

FIG. 7 is a diagram showing one example of setting contents in the table used in the first modified example of the FIR filter according to the first example embodiment;

FIG. 8 is a diagram showing correspondence between input values, address values, and computation results in the first modified example of the FIR filter according to the first example embodiment;

FIG. 9 is a diagram showing one example of setting contents in a table used in a second modified example of the FIR filter according to the first example embodiment;

FIG. 10 is a diagram showing correspondence between input values, address values, and computation results in the second modified example of the FIR filter according to the first example embodiment;

FIG. 11 is a diagram for describing the concept of an FIR filter according to the second example embodiment;

FIG. 12 is a diagram showing a configuration example of an FIR filter in a conceptual stage;

FIG. 13 is a diagram showing a modified example of the FIR filter shown in FIG. 12;

FIG. 14 is a diagram showing a configuration example of an FIR filter in a conceptual stage;

FIG. 15 is a diagram showing a modified example of the FIR filter shown in FIG. 14;

FIG. 16 is a diagram showing one example of setting contents in a table used in the FIR filter shown in FIG. 15; and

FIG. 17 is a diagram for describing a flow of processing by the FIR filter shown in FIG. 15;

### EXAMPLE EMBODIMENTS

Example embodiments of the present invention will be described below with reference to the accompanying drawings. Note that the drawings are in simplified form and the technical scope of the example embodiments should not be interpreted to be limited to the drawings. The same elements are denoted by the same reference numerals and a duplicate description is omitted.

In the following example embodiments, when necessary, the present invention is explained by using separate sections or separate example embodiments. However, those example embodiments are not unrelated with each other, unless otherwise specified. That is, they are related in such a manner that one example embodiment is a modified example, an application example, a detailed example, or a supplementary example of a part or the whole of another example embodiment. Further, in the following example embodiments, when the number of elements or the like (including numbers, values, quantities, ranges, and the like) is mentioned, the number is not limited to that specific number except for cases where the number is explicitly specified or the number is obviously limited to a specific number based on its principle. That is, a larger number or a smaller number than the specific number may also be used.

Further, in the following example embodiments, the components (including operation steps and the like) are not necessarily indispensable except for cases where the component is explicitly specified or the component is obviously indispensable based on its principle. Similarly, in the following example embodiments, when a shape, a position relation, or the like of a component(s) or the like is mentioned, shapes or the like that are substantially similar to or resemble that shape are also included in that shape except for cases where it is explicitly specified or they are eliminated based on its principle. This is also true for the above-described number or the like (including numbers, values, quantities, ranges, and the like).

### <Study in Advance by Inventors>

Prior to giving the description of a Finite Impulse Response (FIR) filter 1 according to a first example embodiment, contents studied in advance by the inventors will be described.

### <Description of FIR Filter 50 in Conceptual Stage>

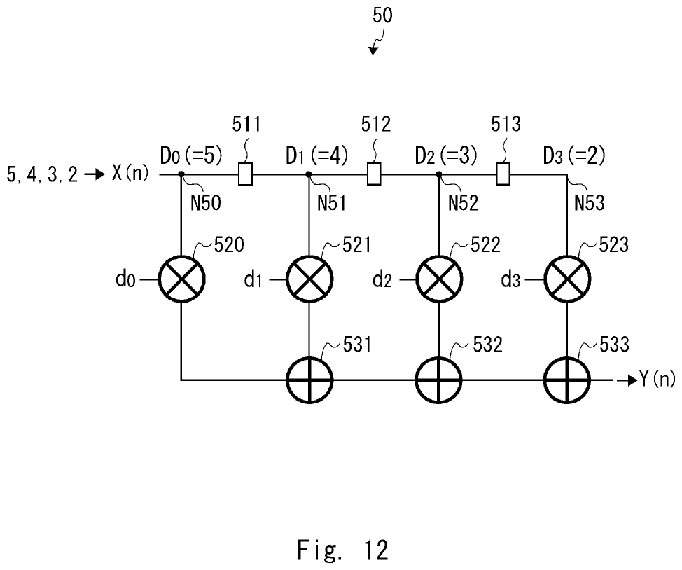

FIG. 12 is a diagram showing a configuration example of an FIR filter 50 in a conceptual stage. In the following, a case where the number of taps (the number of filter coefficients) k of the FIR filter 50 is four will be described. However, it is merely an example, and k may be any integer equal to or larger than two.

As shown in FIG. 12, the FIR filter 50 is an FIR-type digital filter that performs filtering on input data X(n) and outputs output data Y(n), and includes three latch circuits 511-513 whose number corresponds to k−1, four multiplication circuits 520-523 whose number corresponds to k, and three addition circuits 531-533 whose number corresponds to k−1.

As the input data X(n) within a predetermined period up to a time n, four input data items D3, D2, D1, and D0 are input to the FIR filter 50 in series. In the example shown in FIG. 12, four input data items “2”, “3”, “4”, and “5” are input in series as the input data X(n) within the predetermined period up to the time n.

The latch circuits 511-513, which form a shift register, shift the input data D3, D2, D1, and D0 to nodes N53, N52, N51, and N50, respectively. The multiplication circuits 520-523 respectively perform processing of multiplying filter coefficients d0-d3 by the input data D0-D3. The addition circuit 531 performs processing of adding the result of the multiplication performed by the multiplication circuit 520 and the result of the multiplication performed by the multiplication circuit 521. The addition circuit 532 performs processing of adding the result of the addition by the addition circuit 531 and the result of the multiplication performed by the multiplication circuit 522. The addition circuit 533 performs processing of adding the result of the addition by the addition circuit 532 and the result of the multiplication performed by the multiplication circuit 523, and outputs the result of the addition as the output data Y(n). In the example shown in FIG. 12, D0=5, D1=4, D2=3, and D3=2. Therefore, the output data Y(n) can be expressed as follows.

$$\begin{matrix}Y ( n ) = d 0 \times D 0 + d 1 \times D 1 + d 2 \times D 2 + d 3 \times D 3 \\ = 5 \cdot d 0 + 4 \cdot d 1 + 3 \cdot d 2 + 2 \cdot d 3\end{matrix}$$

### <Modified Example of FIR Filter 50 in Conceptual Stage>

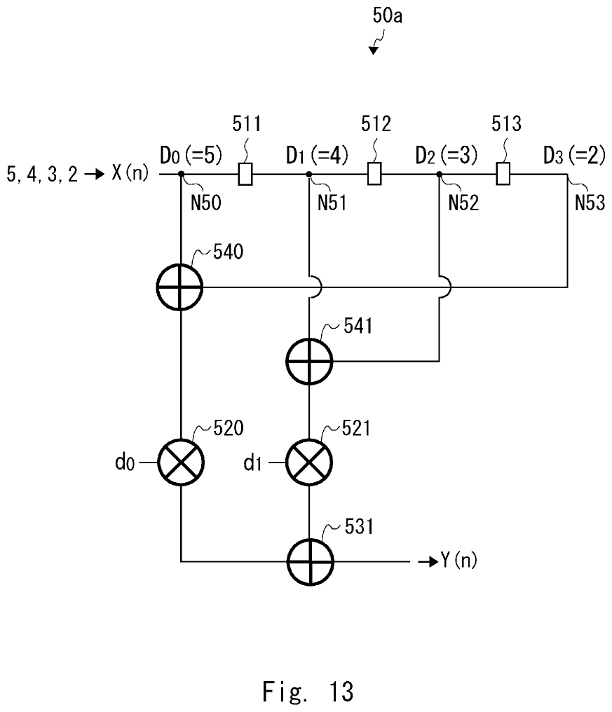

FIG. 13 is a diagram showing a modified example of the FIR filter 50 as an FIR filter 50a. The FIR filter 50a makes the filter coefficients d0-d3 have a symmetric property, and is different from the FIR filter 50 in that the FIR filter 50a further includes addition circuits 540 and 541 and does not include the multiplication circuits 522 and 523 and the addition circuits 532 and 533. That is, the number of multiplication circuits in the FIR filter 50a is substantially half the number of multiplication circuits provided in the FIR filter 50. The filter coefficients d0-d3 having a symmetric property means d0=d3 and d1=d2.

The addition circuit 540 performs processing of adding the input data D0 and the input data D3. The addition circuit 541 performs processing of adding the input data D1 and the input data D2. A multiplication circuit 520 performs processing of multiplying the filter coefficient d0 (=d3) by D0+D3, which is the result of the addition performed by the addition circuit 540. A multiplication circuit 521 performs processing of multiplying the filter coefficient d1 (=d2) by D1+D2, which is the result of the addition performed by the addition circuit 541. An addition circuit 531 performs processing of adding the result of the multiplication performed by the multiplication circuit 520 and the result of the multiplication performed by the multiplication circuit 521, and outputs the result of the addition as the output data Y(n). In the example shown in FIG. 13, D0=5, D1=4, D2=3, D3=2, and d0=d3, d1=d2. Therefore, the output data Y(n) can be expressed as follows.

$$\begin{matrix}Y ( n ) = d 0 \times D 0 + d 1 \times D 1 + d 2 \times D 2 + d 3 \times D 3 \\ = d 0 \times ( D 0 + D 3 ) + d 1 \times ( D 1 + D 2 ) \\ = 7 \cdot d 0 + 7 \cdot d 1\end{matrix}$$

As described above, the FIR filter 50a can be configured using multiplication circuits whose number is smaller than that of the FIR filter 50 since the filter coefficients d0-d3 have a symmetric property, whereby it is possible to reduce the sizes of the circuits. However, there is a problem in the FIR filter 50a that since the size of each multiplication circuit is large, the size of the entire circuit is still large. As a means for solving this problem, the inventors have next discussed an FIR filter in which a variance calculation method is employed.

### <Description of FIR Filter 60 in Conceptual Stage>

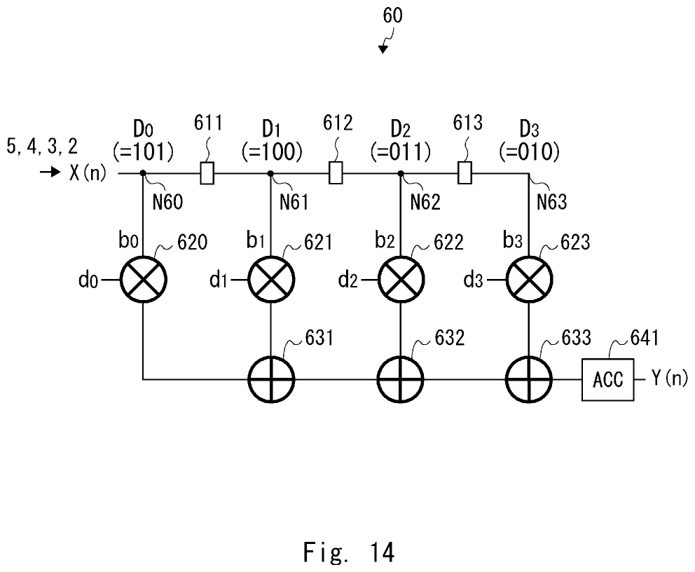

FIG. 14 is a diagram showing a configuration example of an FIR filter 60 in which a variance calculation method is employed. In the following, a case where the number of taps k of the FIR filter 60 is four, like in the FIR filters 50 and 50a, will be described. However, this is merely an example, and k may be any integer equal to or larger than two.

As shown in FIG. 14, the FIR filter 60 is an FIR-type digital filter in which a variance calculation method is employed, and includes three latch circuits 611-613, four multiplication circuits 620-623, three addition circuits 631-633, and an accumulator 641. The latch circuits 611-613 correspond to the latch circuits 511-513, the multiplication circuits 620-623 correspond to the multiplication circuits 520-523, and the addition circuits 631-633 correspond to the addition circuits 531-533.

Four input data items D3, D2, D1, and D0 are input to the FIR filter 60 in series as input data X(n) within a predetermined period up to the time n. In the example shown in FIG. 14, four input data items “2”, “3”, “4”, and “5” are input in series as the input data X(n) within the predetermined period up to the time n.

The latch circuits 611-613 form a shift register, and shift the input data D3, D2, D1, and D0 to nodes N63, N62, N61, and N60, respectively.

The multiplication circuits 620-623 respectively multiply filter coefficients d0-d3 by bit values b0-b3 of the input data D0-D3 having an m (m is an integer equal to or larger than one)-bit width expressed by binary digits at the same bit position.

The addition circuit 631 performs processing of adding the result of the multiplication performed by the multiplication circuit 620 and the result of the multiplication performed by the multiplication circuit 621. The addition circuit 632 performs processing of adding the result of the addition performed by the addition circuit 631 and the result of the multiplication performed by the multiplication circuit 622. The addition circuit 633 performs processing of adding the result of the addition performed by the addition circuit 632 and the result of the multiplication performed by the multiplication circuit 623 and outputs the result of the addition to the accumulator 641.

The accumulator 641 shifts the bits of each of a total of m computation results (the results of the output of the addition circuit 632) for the total of m bit values b0-b3 at the same bit position from the first bit to the m-th bit of each of the input data items D0-D3 having an m-bit width expressed by binary digits in accordance with the bit positions in the respective input data D0-D3, then performs cumulative addition, and outputs the result of the cumulative addition as the output data Y(n).

In the example shown in FIG. 14, D0=5, D1=4, D2=3, and D3=2. When they are expressed by binary digits, D0=101, D1=100, D2=011, and D3=010.

First, the multiplication circuits 620-623 respectively perform processing of multiplying the filter coefficients d0-d3 by the bit values 1, 0, 1, and 0 of the first bit (the least significant bit) of the input data D0-D3 expressed by binary digits. The addition circuit 633 adds up the results of the multiplication, and outputs the result of the addition to the accumulator 641. The result of the output of the addition circuit 633 at this time becomes

(d0×1)+(d1×0)+(d2×1)+(d3×0)=d0+d2.

Next, the multiplication circuits 620-623 respectively perform processing of multiplying the filter coefficients d0-d3 by bit values 0, 0, 1, and 1 of the second bit of the input data D0-D3 expressed by binary digits. The addition circuit 633 adds up the results of the multiplication, and outputs the result of the addition to the accumulator 641. The result of the output of the addition circuit 633 at this time becomes

(d0×0)+(d1×0)+(d2×1)+(d3×1)=d2+d3.

Next, the multiplication circuits 620-623 respectively perform processing of multiplying the filter coefficients d0-d3 by the bit values 1, 1, 0, and 0 of the third bit (the most significant bit) of the input data D0-D3 expressed by binary digits. The addition circuit 633 adds up the results of the multiplication, and outputs the result of the addition to the accumulator 641. The result of the output of the addition circuit 633 at this time becomes

(d0×1)+(d1×1)+(d2×0)+(d3×0)=d0+d1.

The accumulator 641 holds the computation result “d0+d2” for the bit values b0-b3 of the first bit of each of the input data items D0-D3 without shifting bits. Further, the accumulator 641 shifts the bit of the computation result “d2+d3” for the bit values b0-b3 of the second bit of each of the input data items D0-D3 to the left side by one digit and performs cumulative addition. Further, the accumulator 641 shifts the bit of the computation result “d0+d1” for the bit values b0-b3 of the third bit of each of the input data items D0-D3 to the left side by two digits and performs cumulative addition. Then, the accumulator 641 outputs the result of the cumulative addition as the output data Y(n).

Here, the number of combinations of the bit values b0-b3 with the computation results by the multiplication circuits 620-623 and the addition circuits 631-633 is limited to 2 to the power of 4 patterns, that is, 16 patterns. Therefore, the FIR filter 60 performs filter processing using a table 603 in which a plurality of combinations between the bit values b0-b3 and the computation results corresponding to them are set instead of performing filter processing using the multiplication circuits 620-623 and the addition circuits 631-633, so that the size of the circuit can be further reduced.

### <Modified Example of FIR Filter 60 in Conceptual Stage>

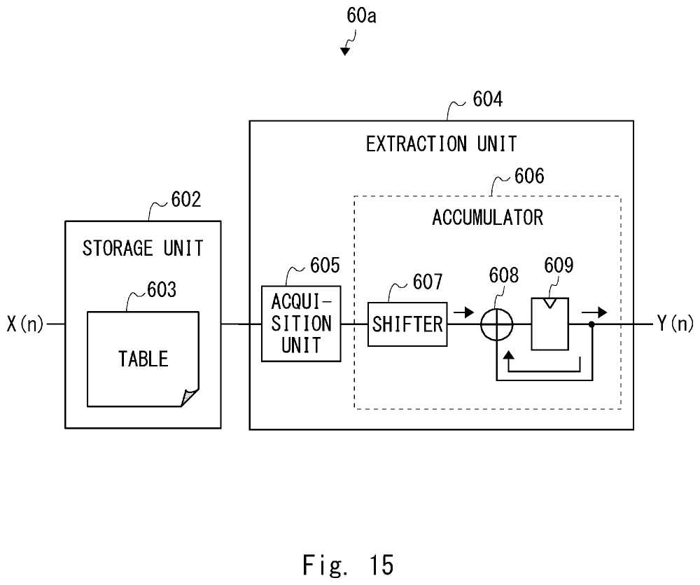

FIG. 15 is a diagram showing a modified example of the FIR filter 60 as an FIR filter 60a. As shown in FIG. 15, the FIR filter 60a includes a storage unit (storage apparatus) 602 and an extraction unit 604.

The storage unit 602 stores a table 603 in which a plurality of combinations of the bit values b0-b3 with the computation results of them are set.

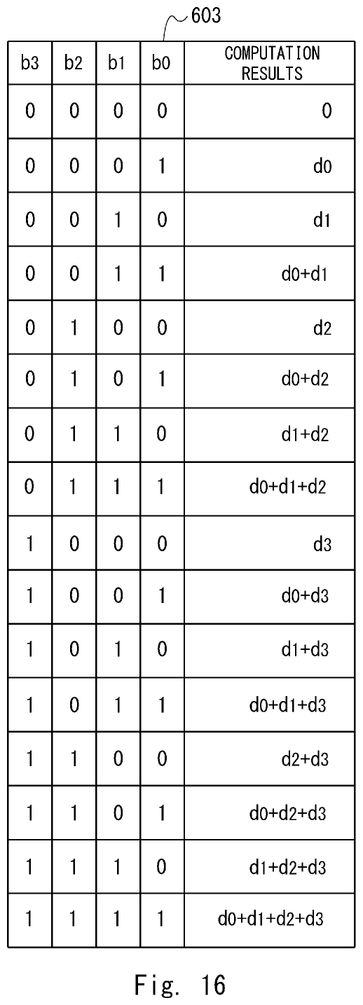

FIG. 16 is a diagram showing one example of setting contents in the table 603. As shown in FIG. 16, 16 patterns of the bit values b0-b3 (in FIG. 16, b3, b2, b1, and b0 are shown in this order) and the computation results corresponding to them are set in the table 603.

The extraction unit 604 extracts, from the table 603, a total of m computation results that correspond to a total of m (in this example, a total of three) bit values b0-b3 at the same bit position from the first bit to the m-th bit (in this example, the third bit) of the input data D0-D3, shifts each of the bits in accordance with the bit positions in the input data D0-D3, and then performs cumulative addition. Then, the extraction unit 604 outputs the result of the cumulative addition as the output data Y(n).

Specifically, the extraction unit 604 includes an acquisition unit 605 and an accumulator 606. The accumulator 606 includes, for example, a shifter 607, an addition circuit 608, and a latch circuit 609.

The acquisition unit 605 reads out computation results of the address values indicated by the bit values b0-b3 from the table 603 stored in the storage unit 102. Alternatively, the acquisition unit 605, which may be a selector, may select, of the 16 patterns of the computation results set in the table 603, a computation result in accordance with the bit values b0-b3 and output the selected computation result.

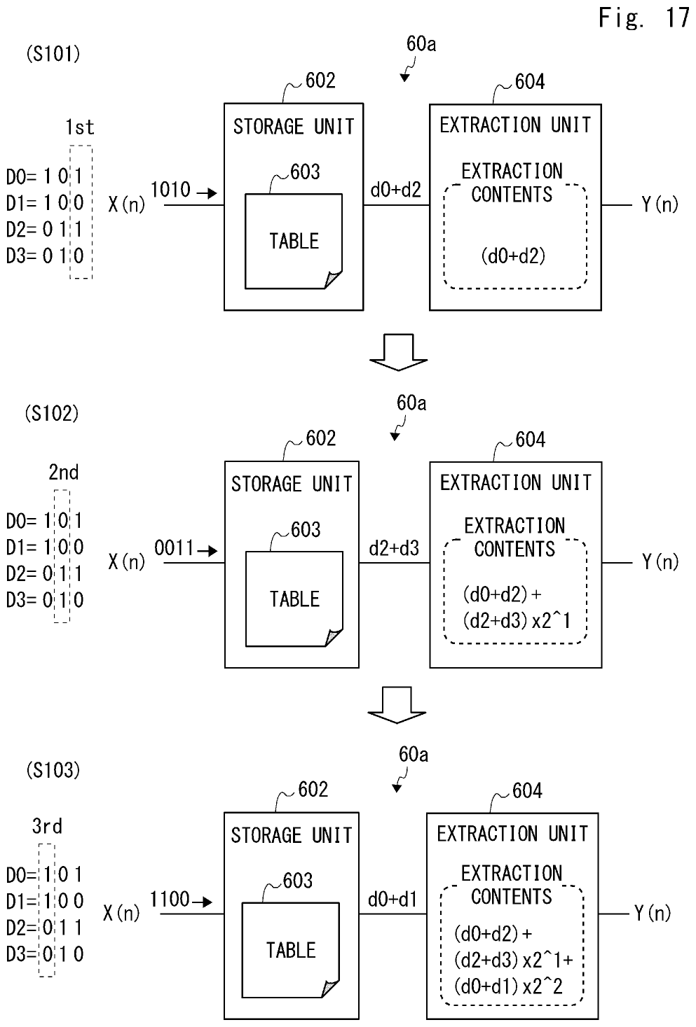

In the accumulator 606, the shifter 607 shifts the bit of the computation result acquired by the acquisition unit 605 in accordance with the bit position in the input data D0-D3 of the bit values b0-b3. When, for example, the computation result “d0+d2” that corresponds to the bit values b0-b3 of the first bit (the least significant bit) has been acquired by the acquisition unit 605, the shifter 607 does not shift the bit of this computation result (see Step S101 of FIG. 17). Further, when the computation result “d2+d3” in accordance with the bit values b0-b3 of the second bit has been acquired by the acquisition unit 605, the shifter 607 shifts the bit of this computation result to the left side by one digit (see Step S102 of FIG. 17). Further, when the computation result “d0+d1” in accordance with the bit values b0-b3 of the third bit (in this example, the most significant bit) has been acquired by the acquisition unit 605, the shifter 607 shifts the bit of the computation result to the left side by two digits (see Step S103 in FIG. 17). The addition circuit 608 and the latch circuit 609 perform cumulative addition of the computation results after bit shifting by the shifter 607. In this example, the addition circuit 608 and the latch circuit 609 perform cumulative addition of three computation results after bit shifting, and outputs the result of the cumulative addition as the output data Y(n).

As described above, the FIR filter 60a performs filter processing using the table 603 instead of performing filter processing using the multiplication circuits 620-623 and the addition circuits 631-633, whereby the size of the circuit can be further reduced. However, there is a problem in the FIR filter 60a that, since the size of the table 603 is large, the size of the entire circuit is still large. Note that the size of the table 603 is exponentially increased in accordance with an increase in the number of taps. Further, when a selector is used as the acquisition unit 605, the size of the selector is increased as well with increasing the size of the table 603.

In order to solve the above-described problem, the inventors have found an FIR filter 1 capable of further reducing the size of the circuit by performing filter processing using a table in which sets of computation results indicating the same values are commonly shared since a plurality of filter coefficients have a symmetric property instead of performing filter processing using multiplication circuits and addition circuits.

### First Example Embodiment

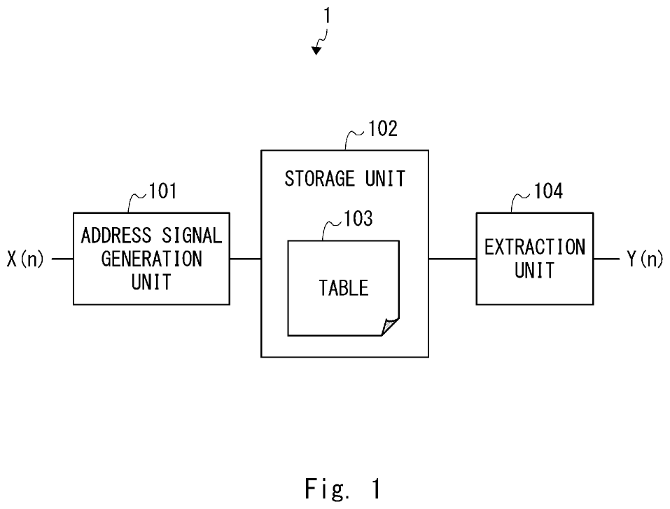

FIG. 1 is a diagram showing a configuration example of an FIR filter 1 according to a first example embodiment. In the following, unless otherwise stated, a case where the number of taps k of the FIR filter 1 is four will be described as an example. However, this is merely an example, and k may be any integer equal to or larger than two.

As shown in FIG. 1, the FIR filter 1 is an FIR-type digital filter in which a variance calculation method is employed, like in the FIR filter 60a, and performs filter processing using a table 103 instead of performing filter processing using multiplication circuits and addition circuits. Further, in the FIR filter 1, filter coefficients d0-d3 have a symmetric property. That is, d0=d3 and d1=d2. In the following, a configuration and an operation of the FIR filter 1 that are different from those of the FIR filter 60a will be mainly described.

As shown in FIG. 1, the FIR filter 1 includes an address signal generation unit 101, a storage unit 102, and an extraction unit 104.

The address signal generation unit 101 generates address signals indicating address values in accordance with a total of m bit values b0-b3 at the same bit position from the first bit to the m-th bit (in this example, the third bit) of each of input data items D0-D3 having an m-bit width expressed by binary digits in series.

More specifically, first, the address signal generation unit 101 generates an address signal indicating an address value in accordance with the bit values b0-b3 of the first bit of each of the input data items D0-D3. Next, the address signal generation unit 101 generates an address signal indicating an address value in accordance with the bit values b0-b3 of the second bit of each of the input data items D0-D3. Next, the address signal generation unit 101 generates an address signal indicating an address value in accordance with the bit values b0-b3 of the third bit of each of the input data items D0-D3.

The storage unit 102 stores a table 103 in which a plurality of combinations of address values indicated by the address signals and the computation results corresponding to them (corresponding to the result of the output in the addition circuit 633 in the FIR filter 60) are set. Here, of 16 patterns (2 to the power of k patterns) of computation results set in a table 603, patterns of computation results in which sets of computation results indicating the same values are commonly shared are set in the table 103. That is, the size of the table 103 is smaller than that of the table 603. The details of setting contents in the table 103 will be described later.

The extraction unit 104 extracts a total of m (in this example, three) computation results that correspond to address values indicated by the address signals generated by the address signal generation unit 101, from the table 103 in series, shifts the bits of the computation results in accordance with the bit positions in the input data D0-D3, and then performs cumulative addition. Then, the extraction unit 104 outputs the result of the cumulative addition as data Y(n).

As described above, the FIR filter 1 according to this example embodiment performs filter processing of filter coefficients having a symmetric property using the table 103 whose size is optimized instead of performing this filter processing by using multiplication circuits and addition circuits, whereby it is possible to further reduce the size of the circuit compared to that in the FIR filter 60a.

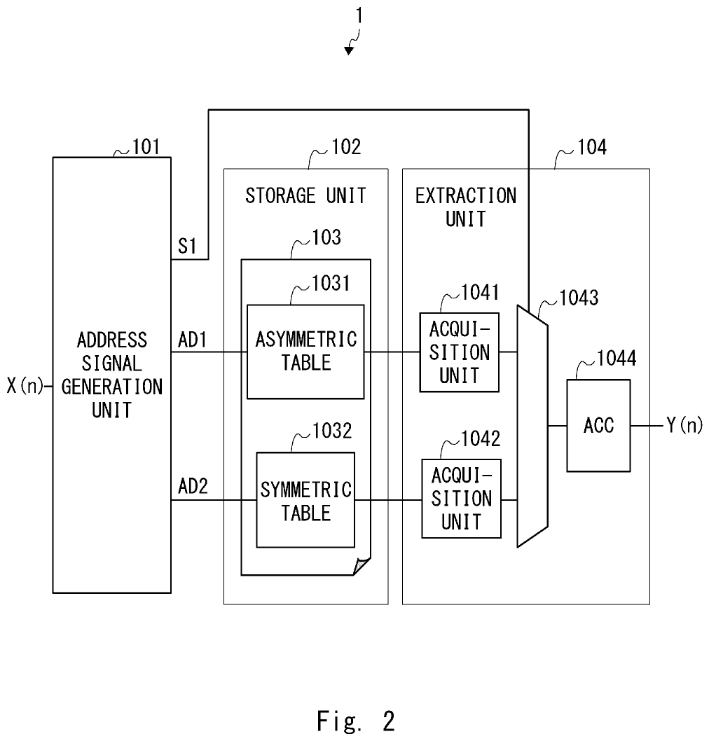

FIG. 2 is a diagram showing a more specific configuration example of the FIR filter 1. As shown in FIG. 2, in the FIR filter 1, the table 103 is formed of a table 1031 and a table 1032. Hereinafter, the table 1031 is referred to as an asymmetric table 1031 and the table 1032 is referred to as a symmetric table 1032. The extraction unit 104 includes acquisition units 1041 and 1042, a selector 1043, and an accumulator (ACC) 1044.

The address signal generation unit 101 generates address signals of address values AD1 and AD2 in accordance with the bit values b0-b3. Hereinafter, the address signal indicating the address value AD1 is also referred to as an address signal AD1. The address signal indicating the address value AD2 is also referred to as an address signal AD2. Further, the address signal generation unit 101 further outputs a selection signal S1 in accordance with the bit values b0-b3.

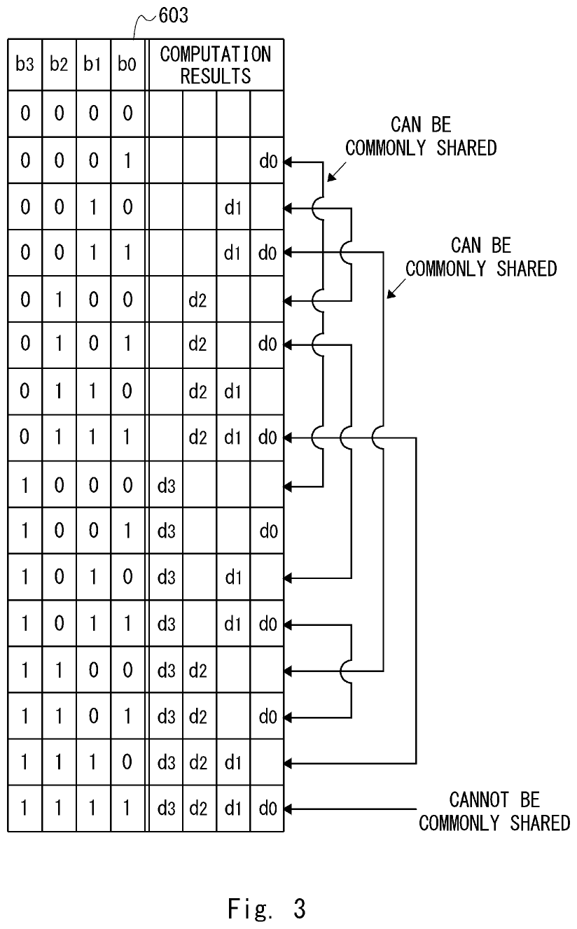

FIG. 3 is a diagram for describing a method for determining the setting contents in the table 103. Note that FIG. 3 shows one example of the setting contents in the table 603. As already described above, in the FIR filter 1, the filter coefficients d0-d3 have a symmetric property. That is, d0=d3 and d1=d2.

Therefore, for example, since the computation result “d0” when the bit values b3, b2, b1, and b0=“0001” and the computation result “d3” when the bit values b3, b2, b1, and b0=“1000” indicate the same value, they can be commonly shared. Further, since the computation result “d1” when the bit values b3, b2, b1, and b0=“0010” and the computation result “d2” when the bit values b3, b2, b1, and b0=“0100” indicate the same value, they can be commonly shared. Further, since the computation result “d1+d0” when the bit values b3, b2, b1, and b0=“0011” and the computation result “d3+d2” when the bit values b3, b2, b1, and b0=“1100” indicate the same value, they can be commonly shared. Further, since the computation result “d2+d0” when the bit values b3, b2, b1, and b0=“0101” and the computation result “d3+d1” when the bit values b3, b2, b1, and b0=“1010” indicate the same value, they can be commonly shared. Further, since the computation result “d2+d1+d0” when the bit values b3, b2, b1, and b0=“0111” and the computation result “d3+d2+d1” when the bit values b3, b2, b1, and b0=“1110” indicate the same value, they can be commonly shared. Further, since the computation result “d3+d1+d0” when the bit values b3, b2, b1, and b0=“1011” and the computation result “d3+d2+d0” when the bit values b3, b2, b1, and b0=“1101” indicate the same value, they can be commonly shared.

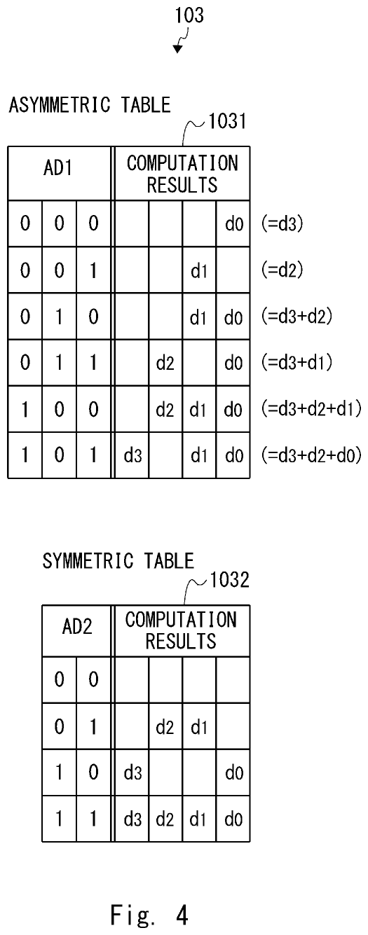

FIG. 4 is a diagram showing one example of setting contents in the table 103. As already described above, the table 103 is formed of the asymmetric table 1031 and the symmetric table 1032. In the asymmetric table 1031, of the 16 patterns of the computation results set in the table 603 shown in FIG. 3, six sets of computation results indicating the same values are commonly shared as six respective patterns of computation results, they are combined with different address values AD1, and then the results of the combination are set. Further, of the 16 patterns of the computation results set in the table 603 shown in FIG. 3, the four remaining computation results other than the six sets of computation results indicating the same values are respectively combined with different address values AD2, and then the results of the combination are set in the symmetric table 1032.

Specifically, each of
a combination of the address value AD1=“000” with the computation result “d0”,
a combination of the address value AD1=“001” with the computation result “d1”,
a combination of the address value AD1=“010” with the computation result “d1+d0”,
a combination of the address value AD1=“011” with the computation result “d2+d0”,
a combination of the address value AD1=“100” with the computation result “d2+d1+d0”, and
a combination of the address value AD1=“101” with the computation result “d3+d1+d0
   is set in the asymmetric table 1031.

Further, each of
a combination of the address value AD2=“00” with the computation result “0 (none)”,
a combination of the address value AD2=“01” with the computation result “d2+d1”,
a combination of the address value AD2=“10” with the computation result “d3+d0”, and
a combination of the address value AD2=“11” with the computation result “d3+d2+d1+d0”
   is set in the symmetric table 1032.

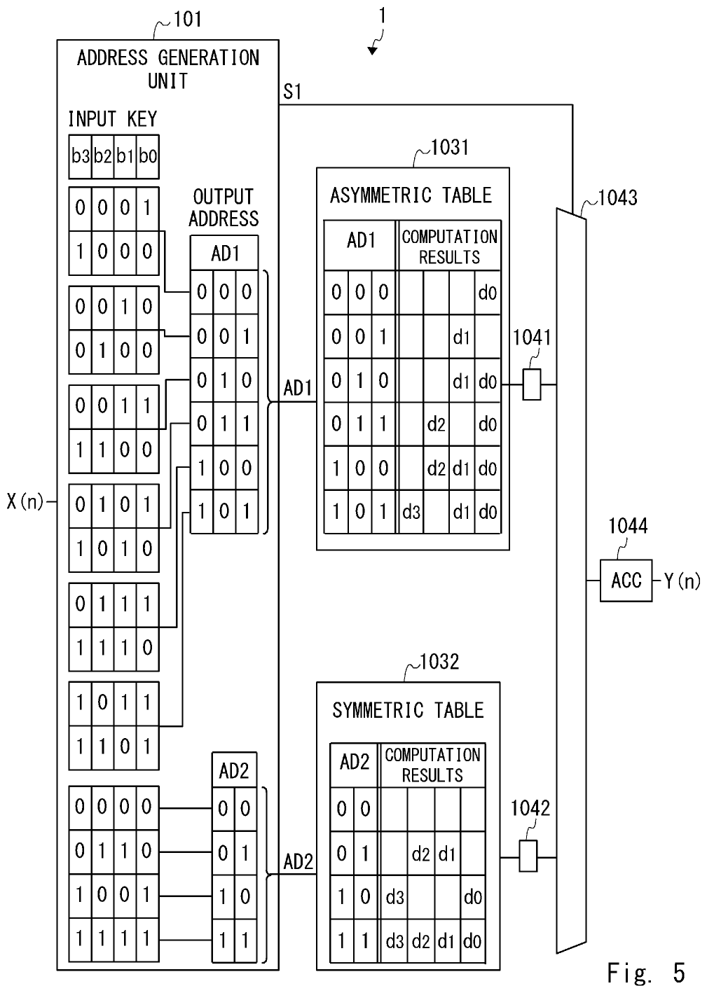

FIG. 5 is a diagram showing correspondence between input values, address values, and computation results in the FIR filter 1. As shown in FIG. 5, in the address signal generation unit 101, of the 16 patterns of the bit values b0-b3, different address values AD1 are allocated to the six respective sets of bit values b0-b3 whose computation results are the same. Further, in the address signal generation unit 101, of the 16 patterns of the bit values b0-b3, different address values AD2 are allocated to the four respective remaining bit values b0-b3.

Specifically, in the address signal generation unit 101,
a common address value AD1=“000” is allocated to each of the bit values b3, b2, b1, and b0=“0001” and “1000”,
a common address value AD1=“001” is allocated to each of the bit values b3, b2, b1, and b0=“0010” and “0100”,
a common address value AD1=“010” is allocated to each of the bit values b3, b2, b1, and b0=“0011” and “1100”,
a common address value AD1=“011” is allocated to each of the bit values b3, b2, b1, and b0=“0101” and “1010”,
a common address value AD1=“100” is allocated to each of the bit values b3, b2, b1, and b0=“0111” and “1110”,
a common address value AD1=“101” is allocated to each of the bit values b3, b2, b1, and b0=“1011” and “1101”.

Further, in the address signal generation unit 101,
an address value AD2=“00” is allocated to the bit values b3, b2, b1, and b0=“0000”,
an address value AD2=“01” is allocated to the bit values b3, b2, b1, and b0=“0110”,
an address value AD2=“10” is allocated to the bit values b3, b2, b1, and b0=“1001”, and
an address value AD2=“11” is allocated to the bit values b3, b2, b1, and b0=“1111”.

Here, the correspondence between the 16 patterns of the bit values b0-b3 and their computation results associated with each other through the address values AD1 and AD2 in FIG. 5 is substantially the same as the correspondence between the 16 patterns of the bit values b0-b3 and their computation results in the table 603 shown in FIG. 3.

The acquisition unit 1041 reads out the computation result of the address value AD1 indicated by the address signal AD1 from the table 1031 stored in the storage unit 102. Alternatively, the acquisition unit 1041, which may be a selector, may select, from the plurality of computation results set in the table 1031, the computation result in accordance with the address value AD1 indicated by the address signal AD1 and output the selected computation result.

The acquisition unit 1042 reads out the computation result of the address value AD2 indicated by the address signal AD2 from the table 1032 stored in the storage unit 102. Alternatively, the acquisition unit 1042, which may be a selector, may select, of the plurality of computation results set in the table 1032, the computation result in accordance with the address value AD2 indicated by the address signal AD2 and output the selected computation result.

The selector 1043 selects, based on the selection signal S1, one of the computation result acquired by the acquisition unit 1041 and the computation result acquired by the acquisition unit 1042 and outputs the selected computation result. That is, the selection signal S1 indicates which one of the address value in the asymmetric table 1031 and the address value in the symmetric table 1032 the address signal generated by the address signal generation unit 101 indicates.

The accumulator 1044 basically has a configuration similar to that of the accumulator 606. The accumulator 1044 shifts the bit of the computation result selected by the selector 1043 in accordance with the bit positions in the input data D0-D3 of the bit values b0-b3 and performs cumulative addition. In this example, the accumulator 1044 performs cumulative addition of 3 (m) computation results after bit shifting that correspond to the bit width of each of the input data items D0-D3 and outputs the result of the cumulative addition as the output data Y(n).

As described above, the FIR filter 1 according to this example embodiment performs filter processing of filter coefficients having a symmetric property using the table 103 whose size is optimized instead of performing this filter processing by using multiplication circuits and addition circuits, whereby it is possible to further reduce the size of the circuit compared to that in the FIR filter 60a. Further, when selectors are used as the acquisition units 1041 and 1042, the size of each of the tables 1031 and 1032 that form the table 103 is decreased. Therefore, the size of each of the acquisition units 1041 and 1042 is decreased as well in accordance with the decrease in the size of each of the tables 1031 and 1032.

If the number of taps is denoted by k, the number of elements of the symmetric table 1032 (the number of computation results set in the symmetric table 1032) a can be expressed as shown in Expression (1).

[Expression 1]

α=2^{┌k/2┐} (1)

Further, the number of elements in the asymmetric table 1031 (the number of computation results set in the asymmetric table 1031) 3 can be expressed as shown in Expression (2).

[Expression 2]

β=(2^{k}−α)/2 (2)

When, for example, the number of taps k is four, from Expressions (1) and (2), the number of elements α of the symmetric table 1032 and the number of elements β of the asymmetric table 1031 are respectively shown as follows.

[Expression 3]

α=2^{┌4/2┐}=2^{┌2┐}=4

[Expression 4]

β=(2⁴−4)/2=(16−4)/2=6

The numbers of elements α and β calculated using Expressions (1) and (2) are respectively the same as the numbers of elements of the symmetric table 1032 and the asymmetric table 1031 shown in FIG. 4.

That is, when the number of taps k is four, the number of elements in the table before the sets of computation results indicating the same values are commonly shared (table before the computation results are commonly shared) is 16 (=2\hat{ }4). On the other hand, the numbers of elements α and β of two tables (two tables after the computation results are commonly shared) after the sets of computation results indicating the same values are commonly shared are 4 and 6, respectively. That is, the total size of the two tables after the computation results are commonly shared is smaller than the size of the table before the computation results are commonly shared.

Further, when the number of taps k is 5, from Expressions (1) and (2), the number of elements α of the symmetric table 1032 and the number of elements β of the asymmetric table 1031 are respectively as follows.

[Expression 5]

α=2^{┌5/2┐}=2^{┌2.5┐}=8

[Expression 6]

β=(2⁵−8)/2=(32−8)/2=12

That is, when the number of taps k is 5, the number of elements in the table before sets of computation results indicating the same values are commonly shared (table before the computation results are commonly shared) is 32 (=2\hat{ }5). On the other hand, the numbers of elements α and β in the two tables after sets of computation results indicating the same values are commonly shared (two tables after the computation results are commonly shared) are 8 and 12, respectively. That is, the total size of the two tables after the computation results are commonly shared is smaller than the size of the table before the computation results are commonly shared.

### <Description of First Modified Example of FIR Filter 1>

When the number of taps k is an odd number, a table in which a plurality of combinations of k−1 input values (bit values) multiplied by k−1 filter coefficients other than the central filter coefficient with the computation results corresponding to them are set may be stored in the storage unit 102. In this case, processing of adding the computation result extracted from the table and the computation result using the central filter coefficient is separately performed.

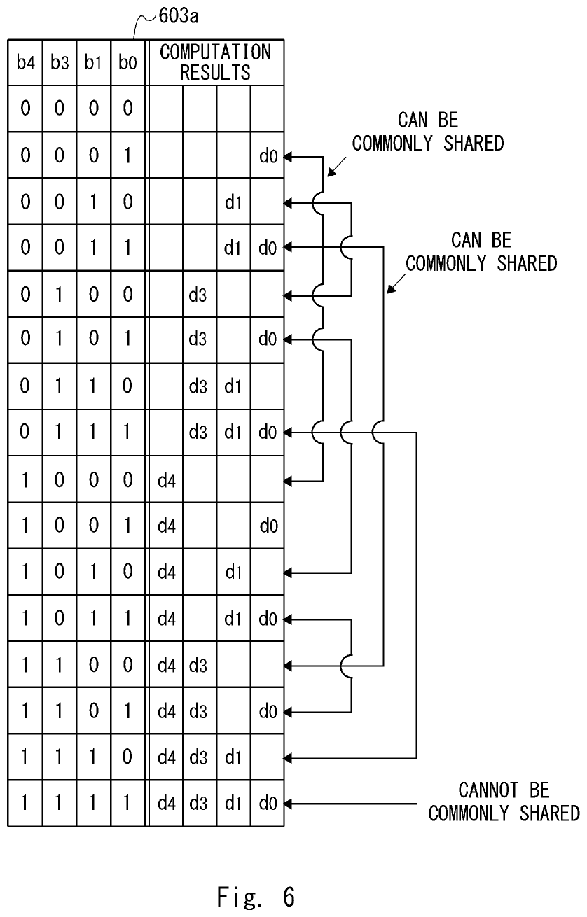

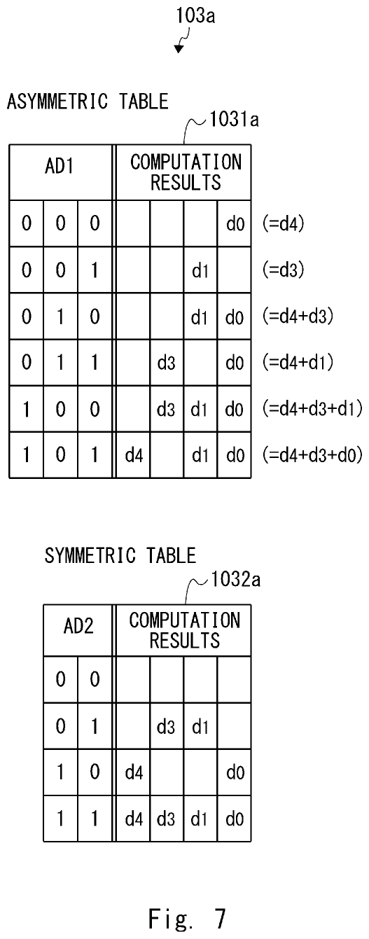

When, for example, the number of taps k is 5, a table 603a in which 16 patterns of combinations of the input values (bit values) b0, b1, b3, and b4 multiplied by filter coefficients d0, d1, d3, and d4 other than the central filter coefficient d2 among five filter coefficients d0-d4 and the computation results corresponding to them are set is prepared first (see FIG. 6). This table 603a is equivalent to the table 603 shown in FIG. 3 except that b3 and b2 in the table 603 are respectively replaced by b4 and b3, and d3 and d2, which are computation results, in the table 603 are respectively replaced by d4 and d3. After that, the table 603a is optimized to a table 103a formed of an asymmetric table 1031a and a symmetric table 1032a as a result of a process similar to that performed in a case where the table 603 is optimized to the table 103 (see FIG. 7). Note that the asymmetric table 1031a and the symmetric table 1032a are equivalent to the asymmetric table 1031 and the symmetric table 1032 except that b3 and b2 in the asymmetric table 1031 and the symmetric table 1032 are respectively replaced by b4 and b3, and d3 and d2, which are computation results, are respectively replaced by d4 and d3.

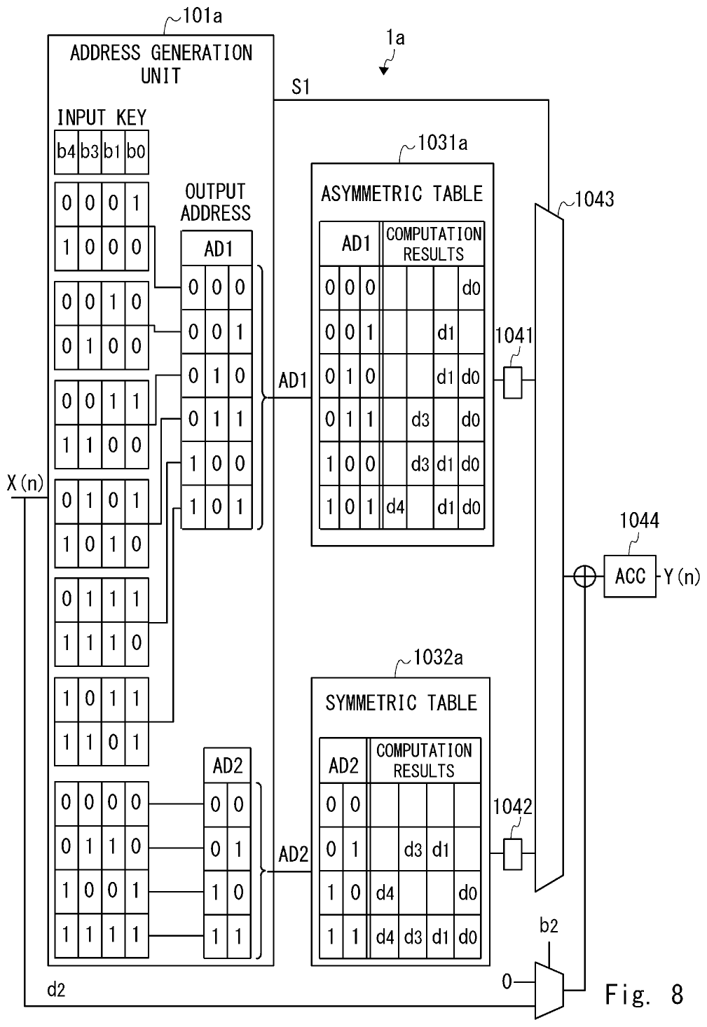

FIG. 8 is a diagram showing correspondence between input values, address values, and computation results in an FIR filter 1a, which is a first modified example of the FIR filter 1. As shown in FIG. 8, in an address signal generation unit 101a, which is a first modified example of the address signal generation unit 101, different address values AD1 are allocated to the six respective sets of bit values b0, b1, b3, and b4 whose computation results are the same among the 16 patterns of the bit values b0, b1, b3, and b4. Further, in the address signal generation unit 101a, different address values AD2 are allocated to the four respective remaining bit values b0, b1, b3, and b4 among the 16 patterns of the bit values b0, b1, b3, and b4.

Here, the correspondence between the 16 patterns of the bit values b0, b1, b3, and b4 and their computation results associated with each other through the address values AD1 and AD2 in FIG. 8 is substantially the same as the correspondence between the 16 patterns of the bit values b0, b1, b3, and b4 and their computation results in the table 603a shown in FIG. 6.

The computation result extracted from the asymmetric table 1031a or the symmetric table 1032a and the result of multiplying the central filter coefficient d2 by the bit value b2 are separately added in an addition circuit provided in the following stage. Since the other configurations of the FIR filter 1a are similar to those of the FIR filter 1, the descriptions thereof will be omitted.

In the FIR filter 1a, the number of elements α in the symmetric table 1032a is four and the number of elements 13 of the asymmetric table 1031a is six. Therefore, the size of each of the tables is further reduced.

### <Description of Second Modified Example of FIR Filter 1>

Further, in the asymmetric table 1031 shown in FIG. 4, further sets of computation results indicating the same values can be commonly shared.

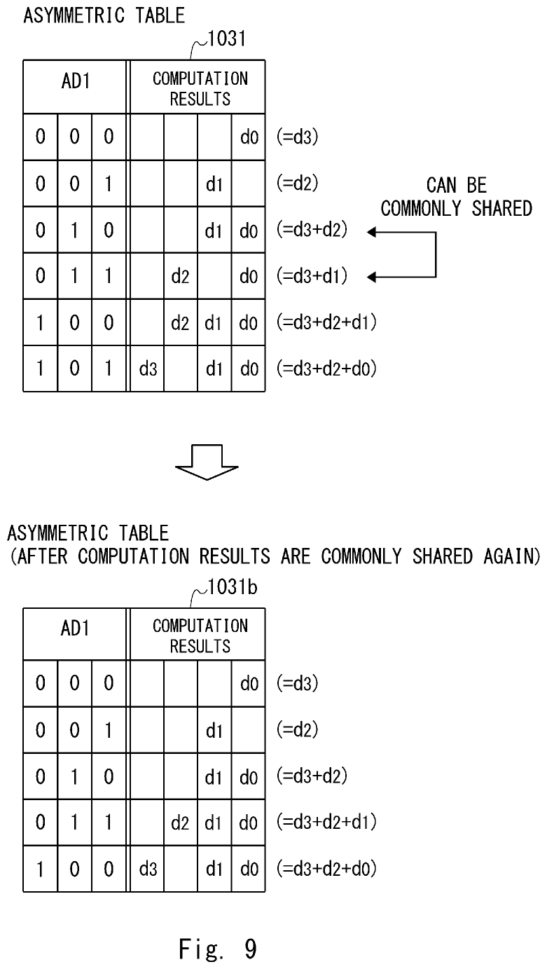

FIG. 9 is a diagram showing one example of setting contents in an asymmetric table 1031b used in an FIR filter 1b, which is a second modified example of the FIR filter 1. As shown in FIG. 9, in the asymmetric table 1031, the computation result “d1+d0” and the computation result “d2+d0” indicate the same value since d3=d0 and d2=d1, and thus they can be commonly shared. Therefore, in the asymmetric table 1031b, the computation result “d1+d0” and the computation result “d2+d0” are commonly shared as the computation result “d1+d0”.

Specifically, each of
a combination of the address value AD1=“000” with the computation result “d0”,
a combination of the address value AD1=“001” with the computation result “d1”,
a combination of the address value AD1=“010” with the computation result “d1+d0”,
a combination of the address value AD1=“011” with the computation result “d2+d1+d0”, and
a combination of the address value AD1=“100” with the computation result “d3+d1+d0”,
   is set in the asymmetric table 1031b.

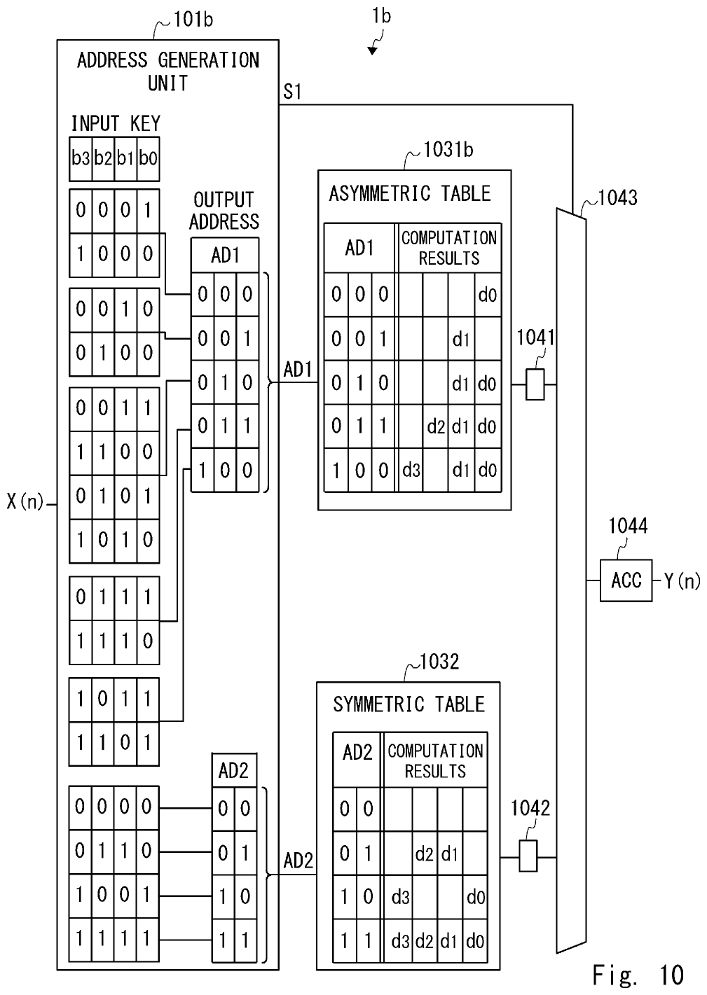

FIG. 10 is a diagram showing correspondence between input values, address values, and computation results in the FIR filter 1b. As shown in FIG. 10, in an address signal generation unit 101b, which is a second modified example of the address signal generation unit 101, different address values AD1 are allocated to four respective sets of bit values b0-b3 whose computation results are the same among 16 patterns of bit values b0-b3. Further, in the address signal generation unit 101b, different address values AD2 are allocated to the four respective remaining bit values b0-b3 among the 16 patterns of the bit values b0-b3.

Note that the correspondence between the 16 patterns of the bit values b0-b3 and their computation results associated with each other through the address values AD1 and AD2 in FIG. 10 is substantially the same as the correspondence between the 16 patterns of the bit values b0-b3 and their computation results in the table 603 shown in FIG. 3.

Since the other configurations of the FIR filter 1b are similar to those of the FIR filter 1, the descriptions thereof will be omitted. In the FIR filter 1b, the number of elements α in the symmetric table 1032a is four and the number of elements β in the asymmetric table 1031b is five. Therefore, the size of each of the tables is further reduced.

### Second Example Embodiment

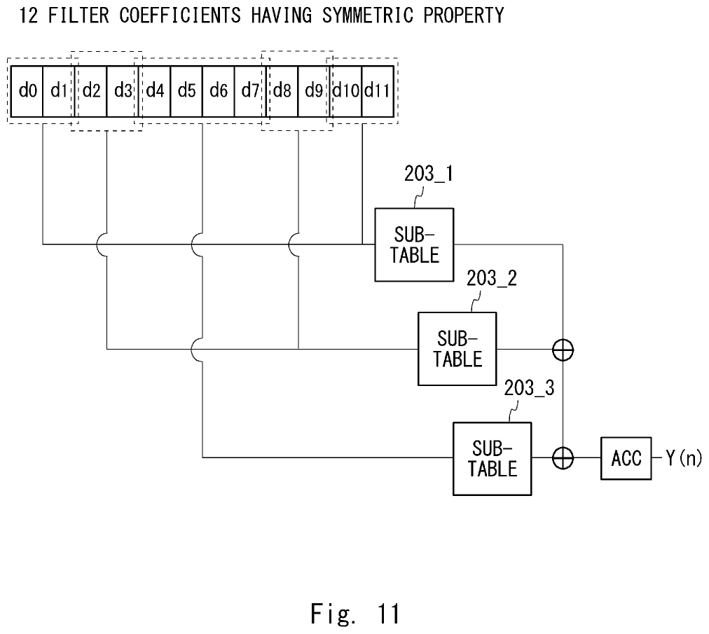

FIG. 11 is a diagram for describing the concept of an FIR filter 2 according to the second example embodiment. When the number of taps k becomes larger, the number of elements in a table is exponentially increased as well in accordance with the increase in the number of taps k. When, for example, the number of taps k is 12, from Expressions (1) and (2), the number of elements α of the symmetric table 1032 is 64 and the number of elements β of the asymmetric table 1031 is 2016. In order to solve this problem, in this example embodiment, the table 103 is divided into a plurality of sub-tables in which a plurality of patterns of computation results for a plurality of filter coefficients having a symmetric property are set.

In the example shown in FIG. 11, a table 103 in which a plurality of patterns of computation results for 12 filter coefficients d0-d11 are set is divided into three sub-tables 203_1-203_3. The computation results extracted from the respective sub-tables 203_1-203_3 are added up by an addition circuit provided in the following stage.

Specifically, a plurality of patterns of computation results for four filter coefficients d0, d1, d10, and d11 having a symmetric property are set in the sub-table 203_1. A plurality of patterns of computation results for four filter coefficients d2, d3, d8, and d9 having a symmetric property are set in the sub-table 203_2. A plurality of patterns of computation results for four filter coefficients d4, d5, d6, and d7 having a symmetric property are set in the sub-table 203_3. Here, each of the sub-tables 203_1-203_3 is formed of a symmetric table whose number of elements α is four and an asymmetric table whose number of elements β is six, like in the case of the example shown with respect to the tables shown in FIG. 4.

That is, a table before it is divided into three sub-tables includes one symmetric table whose number of elements α is 64 and an asymmetric table whose number of elements β is 2016. On the other hand, a table after it is divided into three sub-tables includes three symmetric tables whose number of elements α is four and three asymmetric tables whose number of elements β is six. The size of the table is thus reduced.

The present disclosure can achieve a part or the whole of an FIR filter by causing a Central Processing Unit (CPU) to execute a computer program.

Specifically, the aforementioned program includes instructions (or software codes) that, when loaded into a computer, cause the computer to perform one or more of the functions described in the embodiments. The program may be stored in a non-transitory computer readable medium or a tangible storage medium. By way of example, and not a limitation, computer readable media or tangible storage media can include a random-access memory (RAM), a read-only memory (ROM), a flash memory, a solid-state drive (SSD) or other types of memory technologies, a CD-ROM, a digital versatile disc (DVD), a Blu-ray (registered trademark) disc or other types of optical disc storage, and magnetic cassettes, magnetic tape, magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

While the example embodiments of the present disclosure have been described in detail with reference to the drawings, the specific configurations are not limited to the aforementioned ones and various design changes may be made without departing from the spirit of the present disclosure.

The present disclosure is able to provide an FIR filter, a filtering method by an FIR filter, and a control program capable of preventing the size of a circuit from being increased.

The first and second embodiments can be combined as desirable by one of ordinary skill in the art.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

What is claimed is:

1. An FIR filter comprising:
at least one memory; and
at least one processor configured to execute an instruction stored in the at least one memory, wherein
the at least one processor generates an address signal of an address value in accordance with k (k is an integer equal to or larger than two) bit values that correspond to k filter coefficients having a symmetric property,
the at least one processor extracts a computation result that corresponds to the address value indicated by the generated address signal from a table in which a plurality of address values and a plurality of computation results are associated with each other, the table being stored in a storage apparatus, and
in the table, a plurality of computation results in which sets of computation results indicating the same values among 2 to the power of k patterns of computation results which are obtained by adding up k results of multiplication, the k results of multiplication being results obtained by multiplying each of k filter coefficients having a symmetric property by each of k bit values that correspond to k filter coefficients are commonly shared, and the plurality of address values are associated with each other.

2. The FIR filter according to claim 1, wherein
the table is formed of:
an asymmetric table in which a plurality of first computation results, which are a plurality of computation results commonly shared among the plurality of computation results, and a plurality of first address values associated with the plurality of first computation results among the plurality of address values are set; and
a symmetric table in which a plurality of second computation results, which are a plurality of computation results that are not commonly shared among the plurality of computation results, and a plurality of second address values associated with the plurality of second computation results among the plurality of address values are set,
the at least one processor further outputs, in the generation of the address signals, a selection signal in accordance with the k bit values, and
the at least one processor selects, in the extraction of the computation results, one of a first computation result extracted from the asymmetric table or a second computation result extracted from the symmetric table based on the selection signal and outputs the selected computation result.

3. The FIR filter according to claim 2, wherein, when the number of second computation results set in the symmetric table is denoted by a and the number of first computation results set in the asymmetric table is denoted by β, α and β are expressed as follows.
[Expression 7]
α=2^{┌k/2┐}
[Expression 8]
β=(2^{k}−α)/2

4. The FIR filter according to claim 2, wherein the plurality of first computation results are a plurality of computation results in which sets of computation results indicating the same values are further commonly shared in a plurality of computation results in which sets of computation results indicating the same values are commonly shared among the 2 to the power of k patterns of computation results.

5. The FIR filter according to claim 1, wherein
the k bit values are values at the same bit position of each of k input data items having an m (m is an integer equal to or larger than one)-bit width, and
in the extraction of the computation results, the at least one processor shifts the bits of m computation results for k bit values in each bit position from the first bit to the m-th bit of each of the k input data items in accordance with the bit position, and adds the m computation results whose bits have been shifted.

6. The FIR filter according to claim 1, wherein
the k filter coefficients having a symmetric property are formed of p (p is an integer equal to or larger than two) filter coefficients having a symmetric property and q (q is an integer equal to or larger than two, and k=p+q) filter coefficients having a symmetric property,
the table is formed of:
a first sub-table in which a plurality of computation results where computation results indicating the same values among 2 to the power of p patterns of computation results obtained by adding up p results of multiplication, the p results of multiplication being results obtained by multiplying each of p filter coefficients having a symmetric property by each of p bit values that correspond to the p filter coefficients, are commonly shared, and a plurality of address values whose number correspond to the plurality of computation results are associated with each other; and
a second sub-table in which a plurality of computation results where computation results indicating the same values among 2 to the power of q patterns of computation results obtained by adding up q results of multiplications, the q results of multiplications being results obtained by multiplying each of q filter coefficients having a symmetric property by each of q bit values that correspond to the q filter coefficients, are commonly shared, and a plurality of address values whose number correspond to the plurality of computation results are associated with each other, and
the at least one processor adds, in the extraction of the computation result, the computation result extracted from the first sub-table and the computation result extracted from the second sub-table and outputs the result of the addition.

7. A filtering method by an FIR filter, the filtering method comprising;
generating an address signal of an address value in accordance with k (k is an integer equal to or larger than two) bit values that correspond to k filter coefficients having a symmetric property;
extracting a computation result that corresponds to the address value indicated by the generated address signal from a table in which a plurality of address values and a plurality of computation results are associated with each other, the table being stored in a storage apparatus, wherein
in the table, a plurality of computation results in which sets of computation results indicating the same values among 2 to the power of k patterns of computation results which are obtained by adding up k results of multiplication, the k results of multiplication being results obtained by multiplying each of k filter coefficients having a symmetric property by each of k bit values that correspond to k filter coefficients are commonly shared, and the plurality of address values are associated with each other.

8. A control program for causing a computer to execute:
processing for generating an address signal of an address value in accordance with k (k is an integer equal to or larger than two) bit values that correspond to k filter coefficients having a symmetric property; and
processing for extracting a computation result that corresponds to the address value indicated by the generated address signal from a table in which a plurality of address values and a plurality of computation results are associated with each other, the table being stored in a storage apparatus;
wherein, in the table, a plurality of computation results in which sets of computation results indicating the same values among 2 to the power of k patterns of computation results which are obtained by adding up k results of multiplication, the k results of multiplication being results obtained by multiplying each of k filter coefficients having a symmetric property by each of k bit values that correspond to k filter coefficients are commonly shared, and the plurality of address values are associated with each other.
